(19) United States
(12) Patent Application Publication
(10) Pub. No.: US 2008/0316851 A1
(43) Pub. Date: Dec. 25, 2008

(54) Semiconductor memory device

(75) Inventors: Masaaki Kinoshita, Kanagawa (JP); Hideki Mitoh, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/213,558

(22) Filed: Jun. 20, 2008

(30) Foreign Application Priority Data
Jun. 22, 2007 (JP) 2007-165087

(51) Int. Cl. G11C 8/00

(52) U.S. Cl. 365/230.05

(57) ABSTRACT

Disclosed is a semiconductor memory device including a plurality of memory cells, each of which is connected to word lines of first and second ports and to bit lines of the first and second ports, and first and second inter-port switches for electrically connecting first bit lines of the first port and second bit lines of the second port when row addresses of the first and second ports match each other.

### REFERENCE TO RELATED APPLICATION

This application is based upon and claims the benefit of the priority of Japanese patent application No. 2007-165087, filed on Jun. 22, 2007, the disclosure of which is incorporated herein in its entirety by reference thereto.

### TECHNICAL FIELD

This invention relates to a semiconductor memory device and, more particularly, to semiconductor memory device having a cell with a plurality of ports.

### BACKGROUND

With the progress in micro-fabrication technologies of semiconductors, the dimension of transistors has so shrunk that the influence of variations in transistor characteristics becomes more remarkable as compared with a case where the dimension of transistors is large. If a variation in transistor characteristics (a difference in ON current between transistors of the same size having identical capabilities) is too large, this can lead to malfunction, namely an inability to perform memory-cell data read/write, by way of example. If operating speed, for example, is lowered in order to avoid a decline in yield and reliability due to malfunctions that accompany a variation in transistor characteristics, this can leads to lowering of performance. If the size of the memory cell is made too large in order to suppress a variation in characteristics due to the shrinkage in transistor dimension, this enlarges the area of the memory cell.

A dual-port or multiport RAM, which has two ports or multiple ports, is used as an SRAM (Static Random-Access Memory). FIG. 14 is a diagram illustrating an example of the configuration of a typical memory cell of a dual-port RAM (also abbreviated as “Dp-RAM”). As shown in FIG. 14, this memory cell includes a PMOS transistor P01 and an NMOS transistor N03 (drive transistor) connected in series between a power supply terminal and a ground terminal, and a PMOS transistor P02 and NMOS transistor N04 (driver transistor) connected in series between the power supply and ground terminals. These four transistors construct a flip-flop. The gates of the PMOS transistor P01 and NMOS transistor N03 are connected together and are further connected to commonly connected drains of the PMOS transistor P02 and NMOS transistor N04. The gates of the PMOS transistor P02 and NMOS transistor N04 are connected together and are further connected to commonly connected drains of the PMOS transistor P01 and NMOS transistor N03. The memory cell further includes NMOS access transistors N11 and N12 connected between the commonly coupled drains of the PMOS transistor P01 and NMOS transistor N03 and non-inverting bit lines DTA and DTB of A and B ports, and having their gates connected to word lines WLA and WLB of the A and B ports, respectively, and NMOS access transistors N13 and N14 connected between the commonly coupled drains of the PMOS transistor P02 and NMOS transistor N04 and inverting bit lines DBA and DBB of the A and B ports, and having their gates connected to the word lines WLA and WLB of the A and B ports, respectively. This dual port memory cell is constructed by a total of eight transistors, that is, four transistors (P01, P02, N03 and N04) constituting the flip-flop and four access transistors (N11, N12, N13 and N14) connected to the complementary bit lines at the A and B ports.

Although it is possible in terms of the specifications to access one memory cell from the A and B ports in the dual-port RAM, if this one memory cell is accessed simultaneously from the A and B ports (e.g., if simultaneous READ is performed), the result is a worst-case condition in terms of operation of the dual-port RAM.

FIG. 15 is a diagram useful in describing current paths in a case where a memory cell of a dual-port memory RAM having the configuration shown in FIG. 14 is accessed simultaneously from A and B ports. The drive transistor N03 is shared in common by the A and B ports. It is assumed that the bit lines of the A and B ports have been pre-charged to a high potential. The drive transistor N03, which is in the ON state, discharges the bit lines DTA and DTB of the A and B ports through the access transistors N11 and N12.

If there are variations in the ON currents of the access transistor N11 of the A port and of the access transistor N12 of the B port, then a variation develops between a current I11 that flows into the bit line DTA of the A port and a current I12 that flows into the bit line DTB of the B port.

The foregoing has been described using an area 200-1 (the area on the side connected to the bit lines DTA, DTB) in FIG. 15. Similarly, in an area 200-2 (the area on the side connected to the bit lines DBA, DBB) in FIG. 15, a difference develops between currents that flow into the bit lines owing to variations in the ON currents of the access transistors (N13 and N14).

FIG. 16 is a diagram illustrating the area 200-1 in FIG. 15 in partially extracted form. In order to indicate that the drive transistor N03 is in the discharge state in FIG. 16, a common gate node f02 of the PMOS transistor P01 and NMOS transistor N03 is illustrated as being shorted to the VDD potential (i.e., the NMOS transistor N03 is ON).

In FIG. 16, variations in the ON currents I11 and I12 of the access transistors are variations in currents I11 and I12 in an equivalent circuit shown in FIG. 17. In FIG. 17, the access transistors N11 and N12 and drive transistor N03 of FIG. 16 are represented by resistors R11, R12 and R03, respectively, when the transistors are ON.

In FIGS. 16 and 17, if current I03 that flows through the drive transistor N03 (R03 in FIG. 17) is fixed and the ON current of one access transistor increases, then the ON current of the other access transistor decreases. If the ON currents that flow into the access transistors N11 and N12 are represented by I11 and I12, respectively, then the following holds:

I11+I12=I03 (1)

Equation (1) may be rewritten as each of the following equations:

I11=I03−I12 (1a)

I12=I03−I11 (1b)

The current difference between the currents I11 and I12 is the difference between the discharge capabilities of the bit lines DTA and DTB of the ports A and B.

In an ideal case in which there is no port-to-port variation in the ON currents of the access transistors, the ON current I11 of the A port and the ON current of the B port are equal. As illustrated in FIG. 18, therefore, a bit-line discharge equal to or greater than a sensing-limit difference potential 501 is performed at both of the A and B ports and normal operation is carried out.

If there is a port-to-port variation present in the ON currents of the access transistors, whichever of the ON currents of the access transistors N11 and N12 is on the small side decreases by a large margin and, as a consequence, bit-line discharge is not carried out satisfactorily.

For example, if (ON current I11 on the side of the A port)<(ON current I12 on the side of the B port) holds, bit-line discharge on the side of the A port is not performed satisfactorily and the difference potential of the bit line of the A port declines. Consequently, the difference potential is inadequate for a sense amplifier to operate stably. As a result, the difference voltage of the bit-line pair DTA/DBA falls short of a sensing-limit difference potential 601, as illustrated in FIG. 19 and erroneous sensing (erroneous read) occurs. That is, a malfunction occurs.

Thus, in a case where the same memory cell undergoes simultaneous access to ports A and B in a dual-port RAM, a malfunction such as erroneous sensing of data in the memory cell tends to be caused by a port-to-port variation in the ON currents of the transistors that access the memory cell.

### [Non-Patent Document 1]

A 65 nm Ultra-High Density Dual-port SRAM with 0.71 um² 8T-cell for SoC, Renesas Technology Corporation, Renesas Design Corporation, IEEE 2006 Symposium on VLSI Circuits Digest of Technical Papers

### [Patent Document 1]

Japanese Patent Kokai Publication No. JP-A-4-184788

### [Patent Document 2]

Japanese Patent Kokai Publication No. JP-P2005-346837A

### SUMMARY OF THE DISCLOSURE

In order to deal with the foregoing problem, use is made of a technique in which a variation in characteristics that cannot be suppressed in terms of fabrication process is suppressed by circuit means by adding on a circuit that is not required for circuit operation of the memory. FIGS. 20 and 21 are diagrams excerpted from Non-Patent Document 1. FIGS. 22 to 26 have been created anew by the present inventors in order to describe the structure and operation of Non-Patent Document 1. Results of analysis conducted by the present inventors in regard to the circuit of Non-Patent Document 1 will be described below with reference to FIG. 22, etc.

FIG. 22 illustrates a dual-port RAM that includes a row-address comparator (a circuit that outputs the low level when row addresses match each other) 203; a circuit 201B for disabling word lines of the B port when the row addresses match each other; and, on the side of the B port, a selecting circuit 204 that switches between connection of the bit lines of the A port or B port to a peripheral circuit 202B on the side of the B port depending upon the output of the row-address comparator 203. It should be noted that memory cells in FIG. 22 have the structure shown in FIG. 15.

At the time of access by different row addresses, as illustrated in FIGS. 23 and 25, selected word lines WLAm and WLBn go to the high level and outputs RAC and RACBB of the row-address comparator 203 also go to the high level. The word line WLAm on the side of the A port operates normally at this time.

Since the output RAC of the row-address comparator 203 is at the high level, the word line WLBn on the side of the B port go to the high level. The selecting circuit 204, which is inserted on the side of the B port, disconnects the bit lines of the A port from the peripheral circuit 202B of the B port and connects the bit lines of the B port to the peripheral circuit 202B. As a result, the device operates as a dual-port RAM in the normal mode.

FIG. 25 is a diagram illustrating the waveforms of operation in this case. In time period 121, the output RAC of the row-address comparator 203 is set to the high level because different row addresses are selected. Since the word line WLAm of the A port goes to the high level, the bit line DTA (or DTB) of the A port is discharged by the access transistor of the A port. The word line WLBn of the B port goes to the high level simultaneously. Consequently, the bit line DTB (or DBB) of the B port is discharged by the access transistor of the B port. The device operates similarly as a dual-port RAM in the normal mode in the case of time period 122 as well.

Further, as illustrated in FIG. 24, at the time of access by identical row addresses, selected word lines WLAm and WLBm attain the high and levels, respectively, and outputs RAC, RACBB of the row-address comparator 203 fall to the low level. The word line WLAm on the side of the A port operates normally at this time.

Since the output RAC of the row-address comparator 203 falls to the low level, so does the word line WLBm on the side of the B port. In the selected memory cell, therefore, only the word line WLA of the A port rises and only the bit lines of the port are discharged. The word line of the B port remains disabled and the bit lines of the B port are not discharged. Furthermore, the selecting circuit 204, which has been inserted on the side of the B port, disconnects the bit lines of the B port from the peripheral circuit 202B of the B port, connects the bit lines of the B port to the peripheral circuit 202B and operates upon interchanging the bit lines. In other words, read-out of the A port and B port is performed solely by the bit lines of the A port.

FIG. 26 is a diagram illustrating the waveforms of operation in this case. In time period 131, the output RAC of the row-address comparator 203 falls to the low level because the same row addresses are selected. The word line WLAm of the A port attains the high level and the bit line DTA (or DTB) is discharged through the access transistor of the A port. Since the word line WLBm of the B port falls to the low level at this time, the access transistors of the B port turn off and discharge of the bit line DTB (and DBB as well) of the B port is not performed. In other words, only the word line of the A port and bit lines of the A port operate. Similarly, in the case of time period 132 as well, when access is performed by the same row addresses, only the word line WLAn of the A port attains the high level and the word line WLBn of the B port falls to the low level. Operation is similar to that in time period 131.

The object of the circuit in Non-Patent Document 1 is stable operation of a memory cell, an improvement in static noise margin (static characteristics) and an improvement in access time. At the time of same-address access in the circuit configuration of Non-Patent Document 1, only the access transistors on the side of the A port are used, the access transistors on the side of the B port are not used and only the port on one side is used. That is, the circuit is advantageous in that there is no influence from port-to-port variation of the access transistors.

Thus, with regard to the circuit configuration of Non-Patent Document 1, although there is no influence from port-to-port variation of the access transistors, it is required that the addresses be input synchronously at the A and B ports.

In a case where a dual-port RAM is used as a randomly accessible circuit, it is necessary that the A and B ports have separate clocks and that they be operated independently.

With the circuit of Non-Patent Document 1, however, the clock is only that of a single channel and it is required that the ports be operated in synch with the single-channel clock. This means that the circuit of Non-Patent Document 1 is not suitable for asynchronous random access.

FIG. 27 illustrates the circuit configuration disclosed in Patent Document 1. The circuit of Patent Document 1 aims to shorten write time by short-circuiting the bit line of one port and the bit line of the second port in a case where the word lines of a memory cell are accessed simultaneously from both ports in a state in which one port is in the write state with respect to the memory cell.

When one port is in the write state with respect to a certain memory cell, the fact that the row addresses of both ports match each other is sensed by a sensing circuit 4. That is, when the word lines on the sides of both ports connected to the memory cell are both being accessed, the sensing circuit 4 outputs the low level as a sense signal Sd. In the period of time during which the sensing signal Sd is at the low level, a bit line BL in the write state and a bit line BL′ of the inverse port connected to the bit line B1 via transfer gates are short-circuited by a first shorting circuit 5. Accordingly, the transfer gates are connected in parallel and the combined resistance thereof becomes half the resistance of one transfer gate. As a result, the time needed for writing is shortened.

The configuration described in Patent Document 1 illustrated in FIG. 27 is such that the bit lines have a switch 2, the sensing circuit 4 (row-address comparator) and the first shorting circuit 5, and operation is such as to afford an improvement at write time. This is entirely different from the present invention, described later. The object of Patent Document 1 is to speed up writing at the time of access by identical row addresses, and therefore each of the ports requires a switch to achieve shorting. The amplifier sides therefore have switches for shorting purposes. That is, switches are required between both ports and the peripheral circuit.

In Patent Document 2, there is disclosed a two-port SRAM in which a column switch is provided with A-port switches, B-port switches and inter-port switches. When it is detected that an A-port row address and a B-port row address match each other, all of the B-port switches are turned off, and an A-port bit line pair for a column selected according to A-port column decode signals is coupled to an A-port data line pair, while an A-port bit line pair for a column selected according to B-port column decode signals is coupled via the inter-port switch to a B-port data line pair. However, the two-port SRAM in Patent Document 2, is configured such that when it is detected that the A-port row address and the B-port row address match each other, the A-port word line and the B-port word line are not driven simultaneously but only the A-port word line is driven, thereby preventing decrease in data read speed and malfunctions.

It is therefore an object of the present invention to provide a semiconductor memory device in which even if there are variations in the ON currents of access transistors of different ports in a multiport cell, the influence of such variations is reduced.

The invention disclosed in this application has the structure set forth below in order to solve the foregoing problems.

According to a first aspect of the present invention, the foregoing object is attained by providing a semiconductor memory device having memory cells connected to word lines of a plurality of ports and to bit lines of the plurality of ports, wherein there are provided inter-port switches for electrically connecting bit lines of different ports corresponding to the word lines of different ports selected simultaneously from among the word lines of the plurality of ports connected to the memory cells.

In the present invention, the inter-port switches are disposed in any form among the following: a form in which at least one is disposed in the direction of an extension of the bit lines; a form in which a plurality are dispersed in a prescribed spaced-apart relationship with each other in the direction of an extension of the bit lines; and a form in which the inter-port switches are disposed in correspondence with each memory cell.

In the present invention, the bit lines of the different ports which are electrically coupled via said inter-port switch, are driven by a drive transistor in the memory cell via respective access transistors of the different ports in the memory cell.

The present invention further provides a semiconductor memory device having a memory cell connected to word lines of at least first and second ports and to bit-line pairs of at least first and second ports and comprising: a first inter-port switch inserted between a positive-logic bit line of the bit-line pair of the first port and a positive-logic bit line of the bit-line pair of the second port; a second inter-port switch inserted between a negative-logic bit line of the bit-line pair of the first port and a negative-logic bit line of the bit-line pair of the second port; and a row-address comparator circuit for comparing the row addresses of the first and second ports and outputting a signal, which turns on the first and second inter-port switches, when the two row addresses match each other.

In the present invention, the row-address comparator circuit turns on the first and second inter-port switches when a word line of the first port and a word line of the second port become active simultaneously and turns off the first and second inter-port switches when one or both of the word line of the first port and word line of the second port is/are inactive.

In the present invention, a pair of the first and second inter-port switches may be disposed with respect to a plurality of memory cells connected to the bit-line pairs of the first and second ports.

In the present invention, one set of first and second inter-port switches may be disposed in correspondence with the memory cell.

In the present invention, the row-address comparator circuit may include a logic circuit for receiving word lines of the first and second ports as respective inputs instead of the row addresses of the first and second ports, and outputting a signal, which turns on the first and second inter-port switches, when the word lines of the first and second ports are both in the active state.

In the present invention, a plurality of sets of said first and second inter-port switches may be disposed in a dispersed manner in areas, each of which supplies a group of memory cells with well potential.

The meritorious effects of the present invention are summarized as follows.

The present invention is such that even if there are variations in the ON currents of access transistors of different ports, the influence of such variations can be reduced. The reason for this is that in the present invention, the arrangement is such that when the word lines of different ports are accessed simultaneously, the inter-port switches are turned on to render the bit lines of the different ports connected each other, thereby discharging the bit lines of the different ports uniformly.

Still other features and advantages of the present invention will become readily apparent to those skilled in this art from the following detailed description in conjunction with the accompanying drawings wherein examples of the invention are shown and described, simply by way of illustration of the mode contemplated of carrying out this invention. As will be realized, the invention is capable of other and different examples, and its several details are capable of modifications in various obvious respects, all without departing from the invention. Accordingly, the drawing and description are to be regarded as illustrative in nature, and not as restrictive.

### BRIEF DESCRIPTION OF THE DRAWINGS

FIG. 1 is a diagram illustrating a circuit configuration according to an exemplary embodiment of the present invention;

FIG. 2 is a diagram illustrating a circuit configuration according to this exemplary embodiment of the present invention;

FIG. 3 is a diagram useful in describing operation in a case where there is a variation between ports (I11<I12) in this exemplary embodiment of the present invention;

FIG. 4 is a diagram useful in describing operation in a case where there is a variation between ports (I11>I12) in this exemplary embodiment of the present invention;

FIG. 5 is a diagram useful in describing operation in a case where there is no variation between ports (I11=I12) in this exemplary embodiment of the present invention;

FIG. 6 is a diagram illustrating voltage waveforms in a case where there is a variation between ports (I11≠I12) in this exemplary embodiment of the present invention;

FIG. 7 is a diagram illustrating voltage waveforms in a case where there is a no variation between ports (I11=I12) in this exemplary embodiment of the present invention;

FIG. 8 is a diagram illustrating voltage waveforms at the time of same-row-address access in this exemplary embodiment of the present invention;

FIG. 9 is a diagram illustrating voltage waveforms at the time of different-row-address access in this exemplary embodiment of the present invention;

FIG. 10 is a diagram illustrating voltage waveforms in an asynchronous case (i.e., rise timing of word line WLA is earlier) in this exemplary embodiment of the present invention;

FIG. 11 is a diagram illustrating voltage waveforms in an asynchronous case (i.e., rise timing of word line WLB is earlier) in this exemplary embodiment of the present invention;

FIG. 12 is a diagram illustrating a circuit configuration according to another exemplary embodiment of the present invention;

FIG. 13 is a diagram illustrating a circuit configuration according to a further exemplary embodiment of the present invention;

FIG. 14 is a diagram illustrating the configuration of a memory cell of a dual-port RAM;

FIG. 15 is a diagram illustrating currents that flow through access transistors in the dual-port RAM;

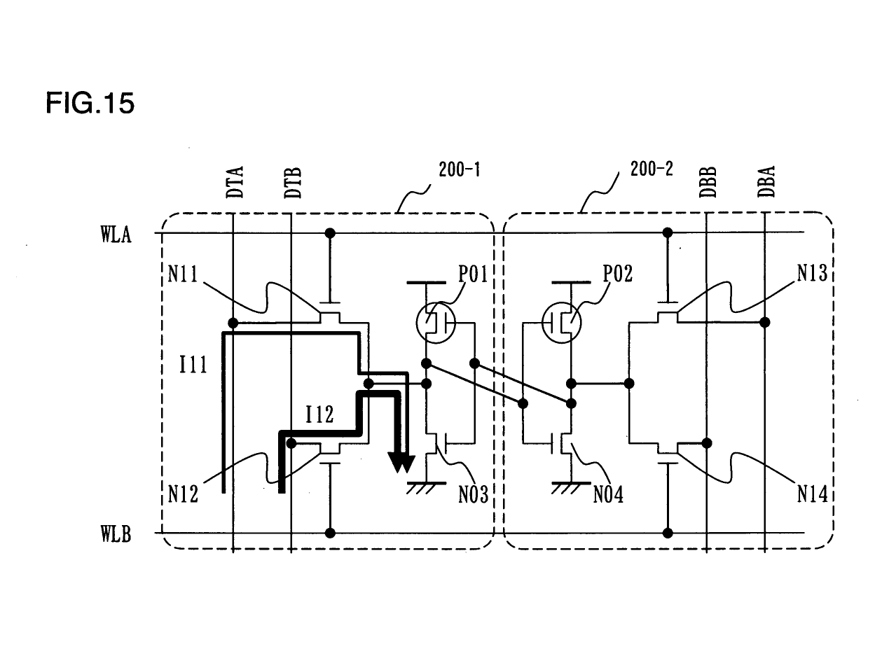

FIG. 16 is a diagram illustrating the circuit of an area 100-1 of the dual-port RAM shown in FIG. 15;

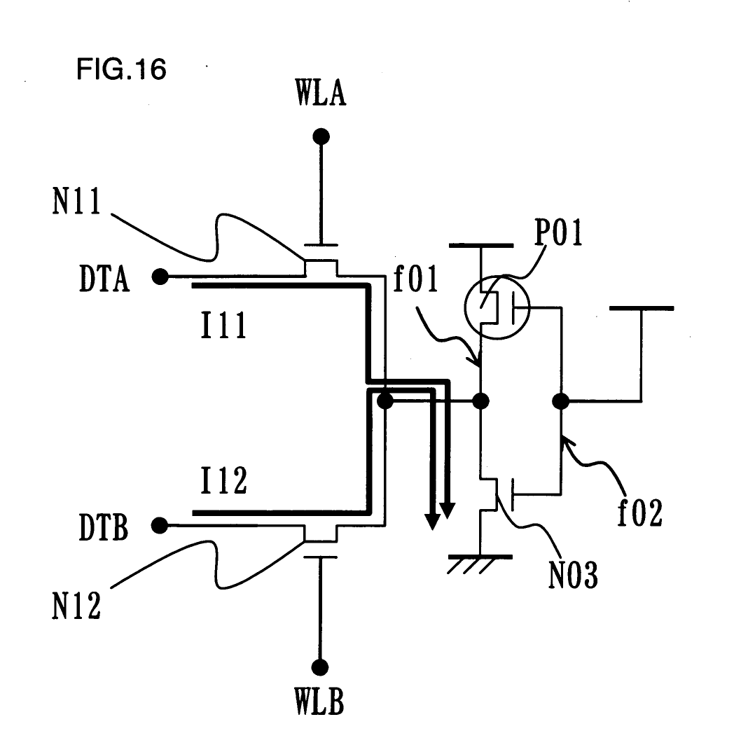

FIG. 17 is a diagram illustrating the equivalent circuit of the circuit shown in FIG. 16 and currents that flow through various components;

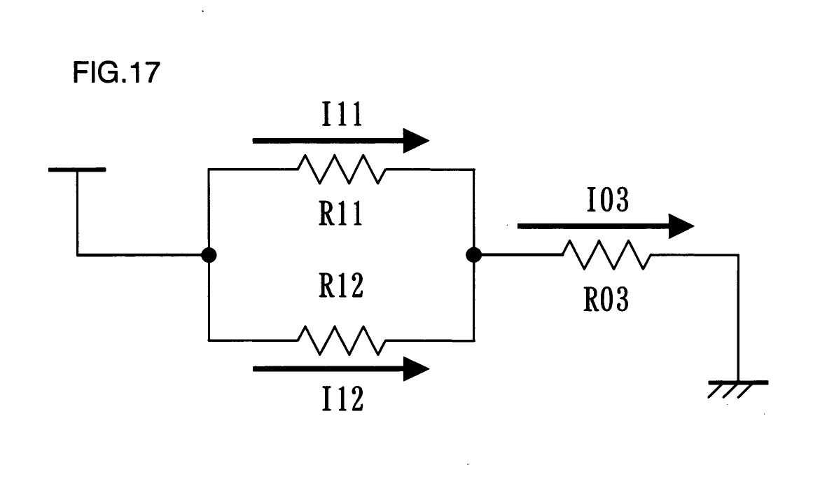

FIG. 18 is a diagram illustrating bit-line discharge in a case where there is no variation between ports;

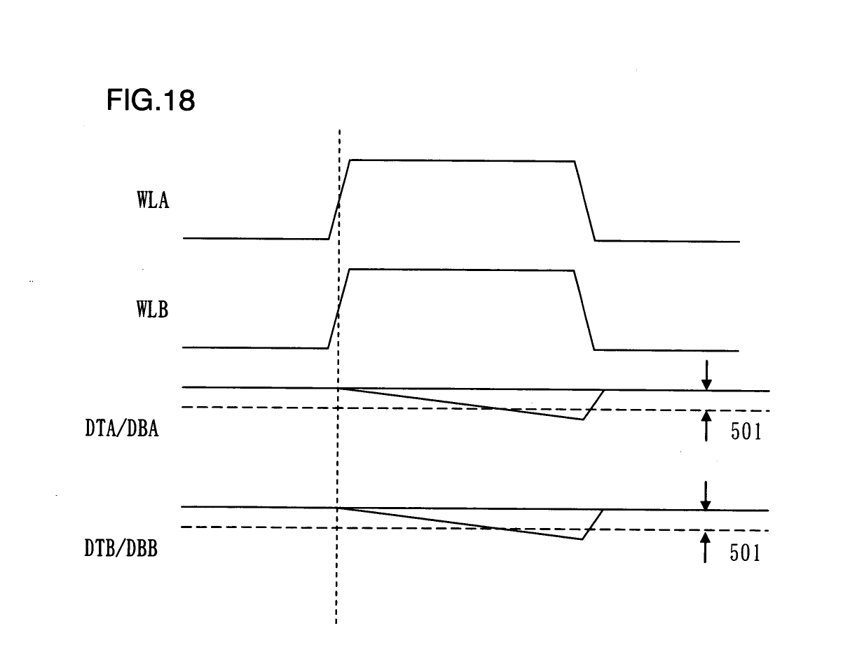

FIG. 19 is a diagram illustrating bit-line discharge in a case where there is variation between ports;

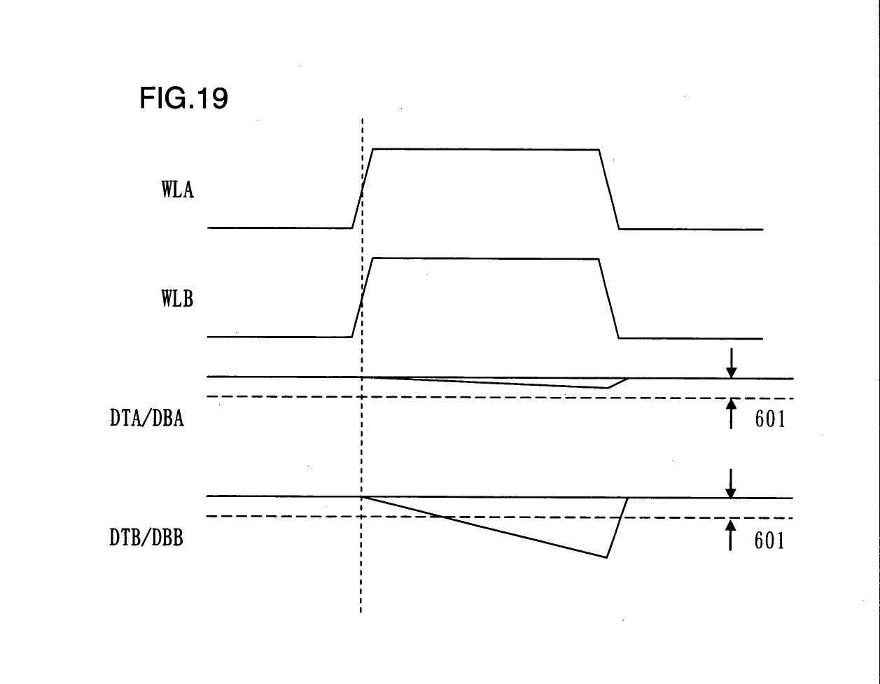

FIG. 20 is a diagram illustrating the circuit configuration and operation of Non-Patent Document 1;

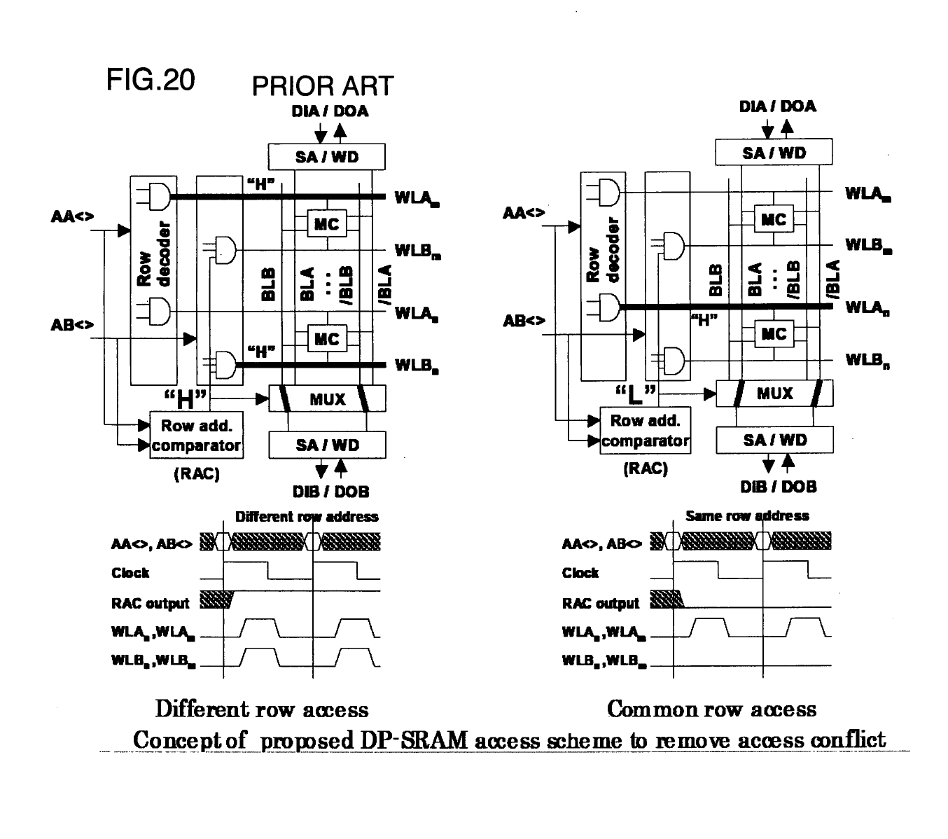

FIG. 21 is a diagram illustrating the arrangement of components in the circuit according to Non-Patent Document 1;

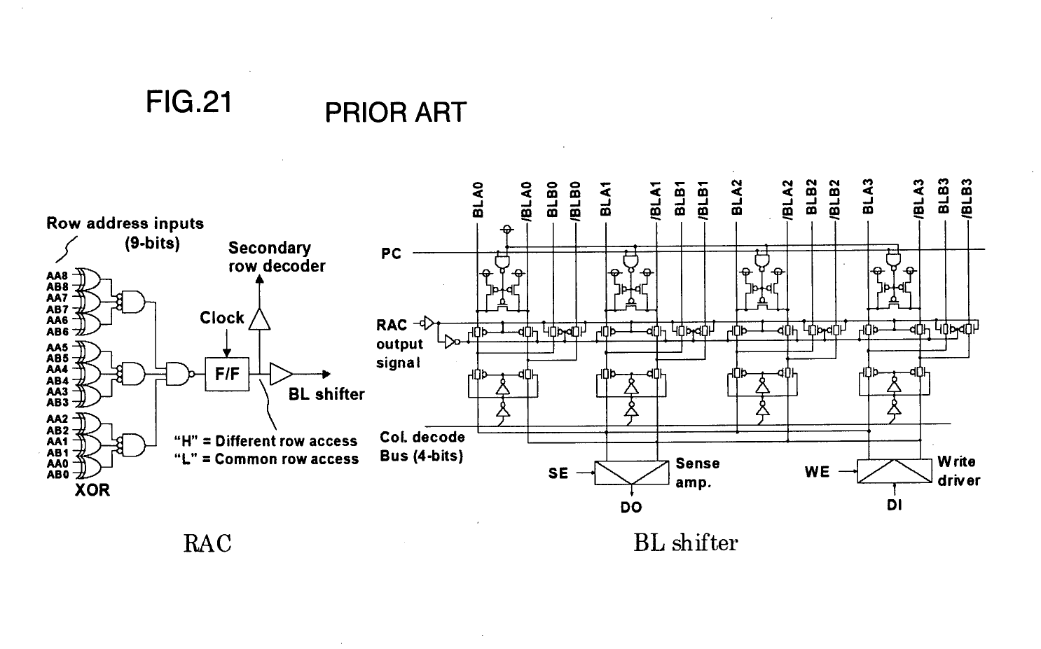

FIG. 22 is a diagram illustrating the circuit configuration of Non-Patent Document 1;

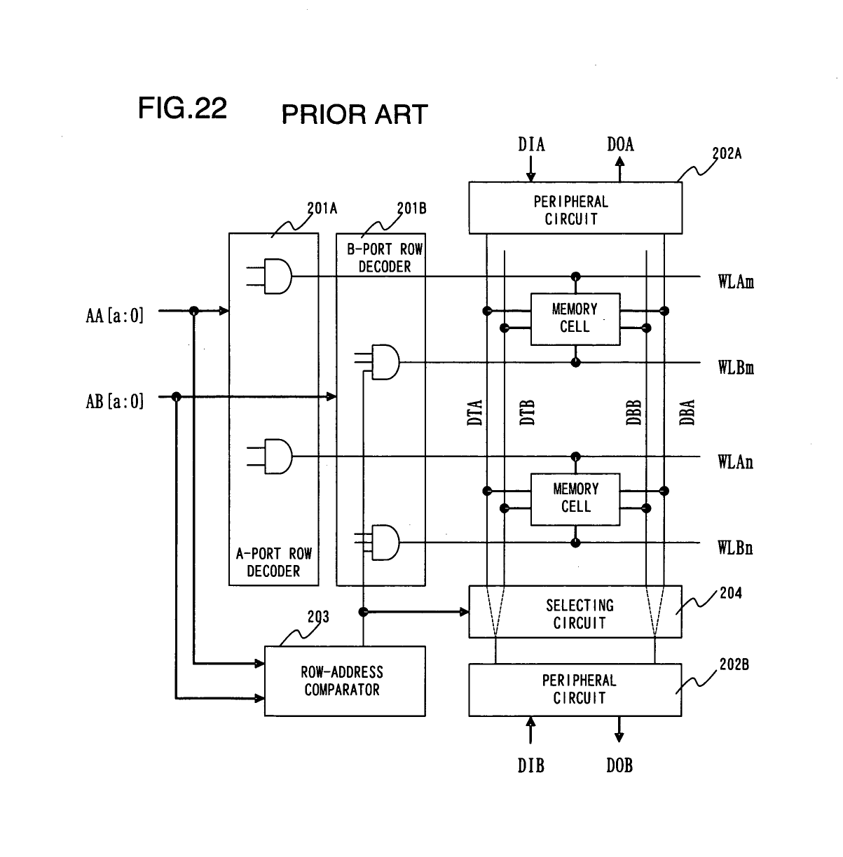

FIG. 23 is a diagram illustrating the circuit configuration and operation (at the time of different-row access) of Non-Patent Document

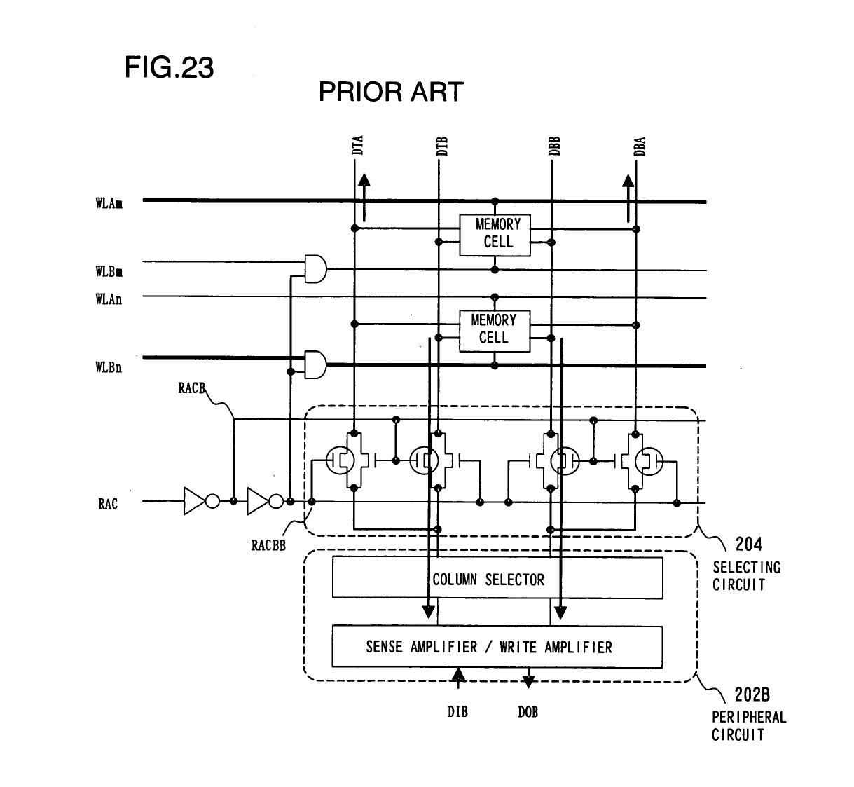

FIG. 24 is a diagram illustrating the circuit configuration and operation (at the time of same-row access) of Non-Patent Document 1;

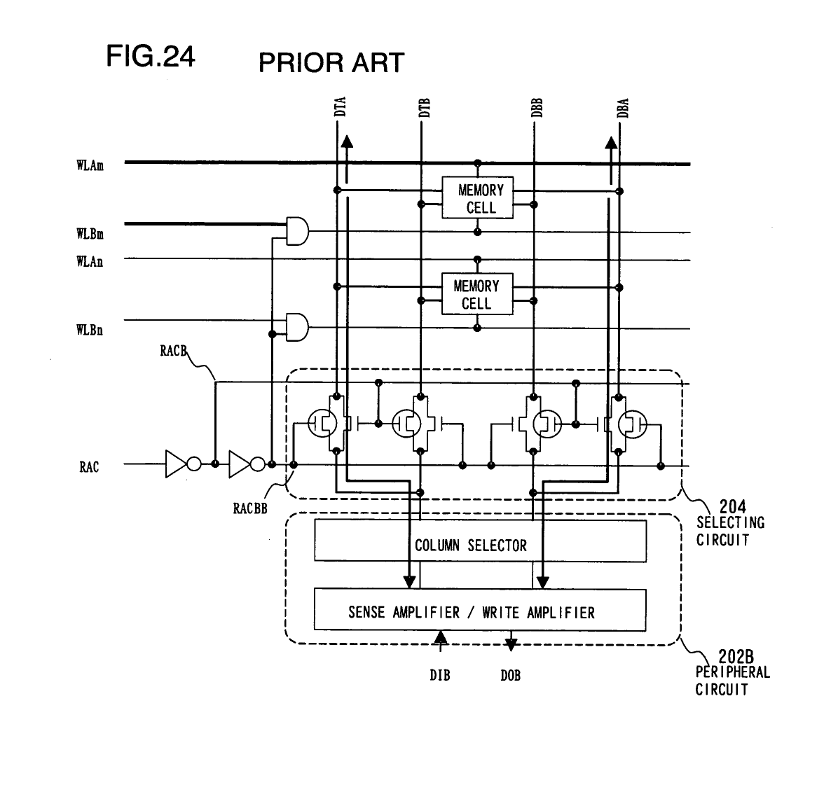

FIG. 25 is a diagram illustrating circuit operation (at the time of different-row access) of Non-Patent Document 1;

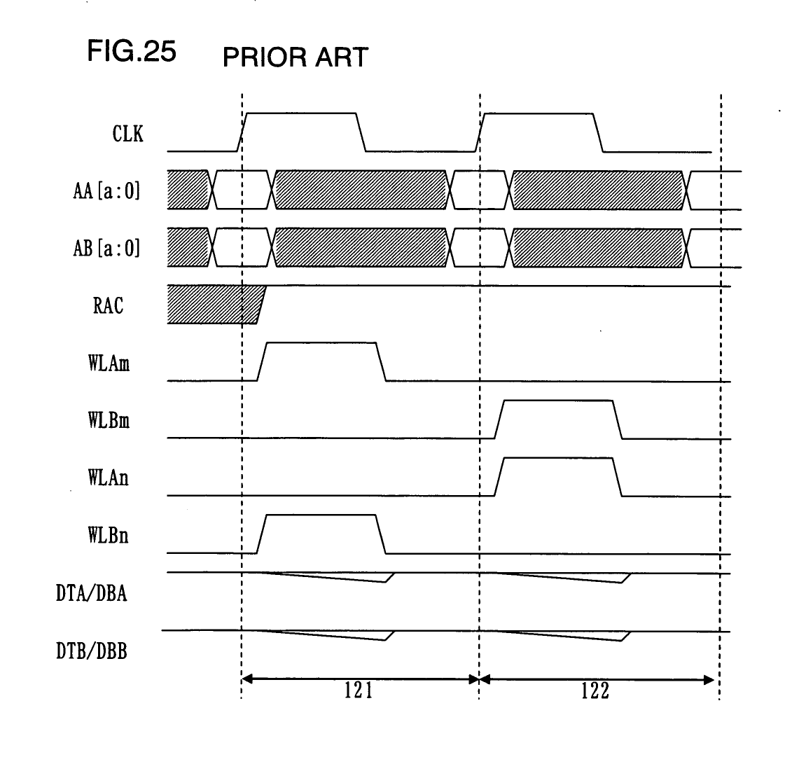

FIG. 26 is a diagram illustrating circuit operation (at the time of same-row access) of Non-Patent Document 1; and

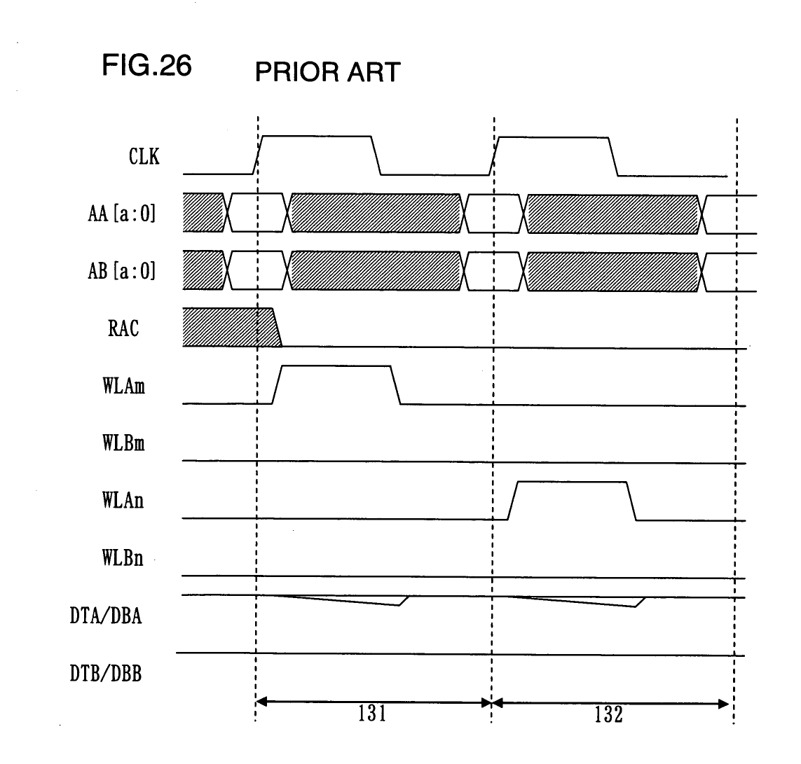

FIG. 27 is a diagram illustrating the circuit configuration of Patent Document 1.

### PREFERRED MODES OF THE INVENTION

The present invention will now be described in detail with reference to the accompanying drawings. The present invention is such that even in case where there are variations in ON currents of access transistors in a multiport RAM (inclusive of a dual-port RAM) connected to word lines of a plurality of ports and to bit lines of the plurality of ports, equal currents flow into the bit lines of A and B ports through inter-port switches when at the time of the same-row-address access, thereby eliminating the effects of port-to-port variation in ON currents of the access transistors and preventing malfunction due to erroneous read.

Even in a case where accessing of A and B ports is asynchronous and random, since the clock is not that of a single channel and operation is possible asynchronously, use in random access is possible. Similarly, the effect of port-to-port variation in ON currents of access transistors is eliminated at this time as well so that malfunction due to erroneous read can be prevented. Exemplary embodiments of the invention will now be described.

### Exemplary Embodiments

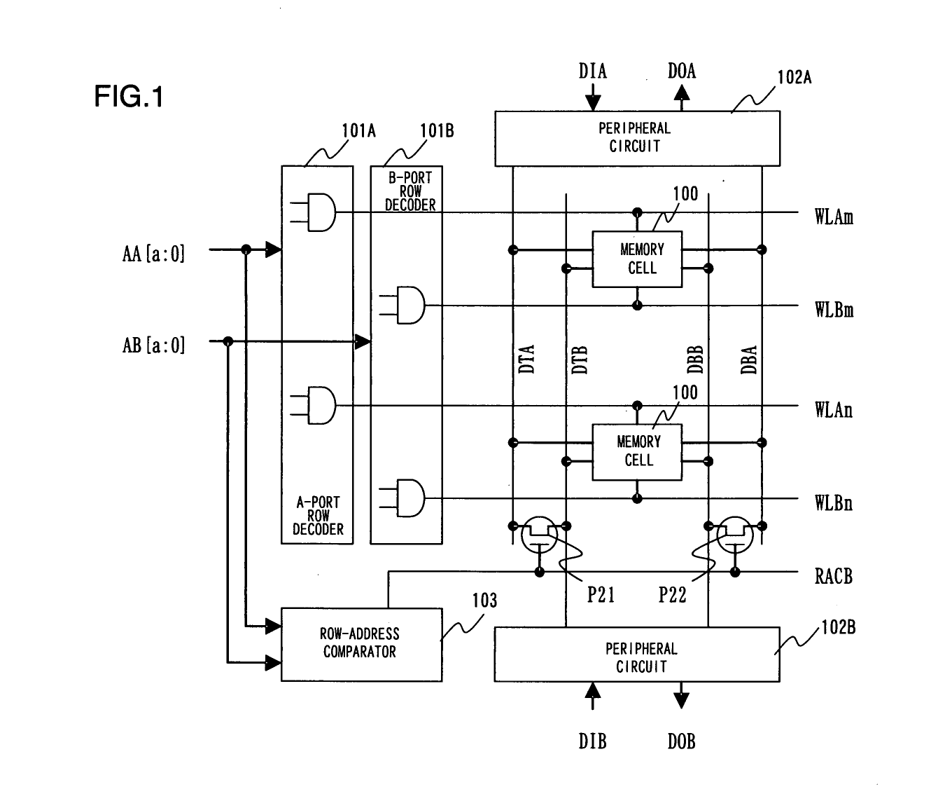

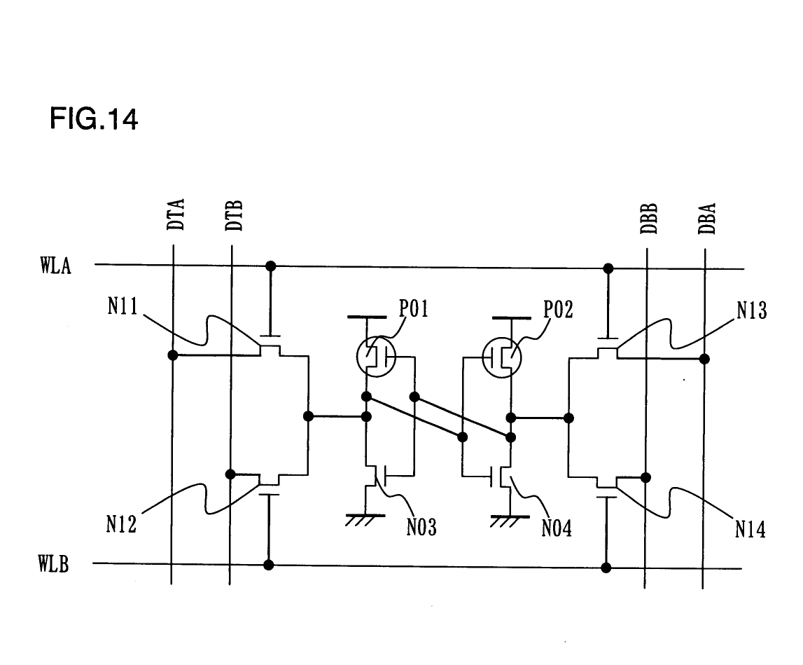

FIG. 1 is a diagram illustrating the configuration of an exemplary embodiment of the present invention. As shown in FIG. 1, a row address AA [a:0] (bit width a+1) of an A port and a row address AB [a:0] (bit width a+1) of a B port are input to a row decoder 101A of the A port and a row decoder 101B of the B port, respectively, the decoders 101A and 101B decode these input signals and select word lines WLA and WLB, respectively, of the A and B ports. A peripheral circuit 102A of the A port has a Y switch (not shown) for selecting bit lines DTA and DBA of the A port, a sense amplifier (not shown) for reading out data, and a write amplifier (not shown) for outputting output data DOA and receiving and writing input data DIA. A peripheral circuit 102B of the B port has a Y switch (not shown) for selecting bit lines DTB and DBB of the B port, a sense amplifier (not shown) for reading out data, and a write amplifier (not shown) for outputting output data DOB and receiving and writing input data DIB. In FIG. 1, bit-line pairs DTA/DBA, DTB/DBB are illustrated with regard to the A and B ports. Memory cells 100 are assumed to be have a structure similar to that shown in FIG. 14.

In the dual-port RAM, illustrated in FIG. 1, an inter-port switch P21 (PMOS pass transistor) is provided between the bit line DTA (the bit line on the positive-logic (non-inverting) side) of the A port and the bit line DTB (the bit line on the positive-logic side) of the B port, and an inter-port switch P22 (PMOS pass transistor) is provided between the bit line DBA (the bit line on the negative-logic (inverting) side) of the A port and the bit line DBB (the bit line on the negative-logic side) of the B port. These inter-port switches P21 and P22 are provided between the positive-logic bit lines of the A and B ports and between the negative-logic bit lines of the A and B ports with regard to each of bit-line pairs not shown.

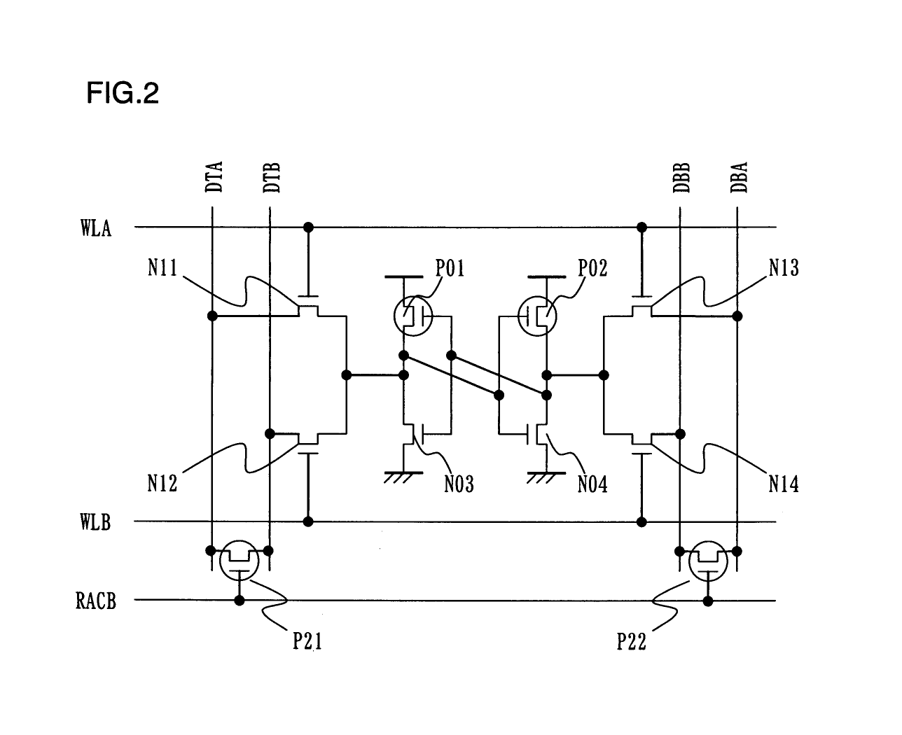

Also is provided a row-address comparator 103 for receiving, as inputs, the row address AA [a:0] (bit width a+1) of the A port and the row address AB [a:0] (bit width a+1) of the B port and performing a comparison to determine whether these inputs agree with each other. The output of the row-address comparator 103 is set to the low level to thereby turn on the inter-port switches P21 and P22 at the time of same-row-address access at the A and B ports (namely when the word lines WLA and WLB of the A and B ports are both selected). When the inter-port switches P21 and P22 turn on, discharge of the bit lines of both ports is performed through the inter-port switches P21 and P22 even if the access transistors (N11, N12, N13, N14 of FIG. 2) in the memory cell 100 develop variations between ports.

FIG. 2 is a diagram illustrating the internal configuration of the memory cell 100 of FIG. 1 as well as the inter-port switches P21 and P22. As illustrated in FIG. 2, this exemplary embodiment is obtained by additionally providing the arrangement of FIG. 14 with the inter-port switch P21 disposed between the bit lines DTA and DTB of the A and B ports, respectively, and with the inter-port switch P22 disposed between the bit lines DBA and DBB of the A and B ports, respectively.

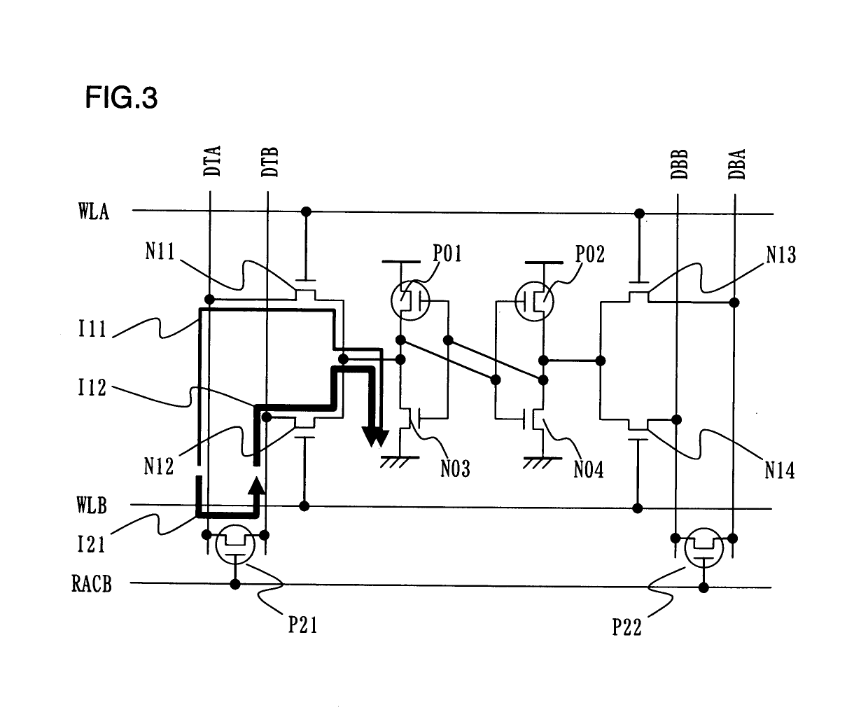

FIG. 3 illustrates the current paths in a case where the ON currents I11 and I12 of the access transistors N11 and N12 in FIG. 2 satisfy the relation I11<I12.

Owing to short-circuiting of the bit line DTA of the A port and the bit line DTB of the B port by the inter-port switch P21, the bit line DTA of the A port is discharged from the high level through the inter-port switch P21 via the path of the bit line DTB of the B port and access transistor N12 of the B port.

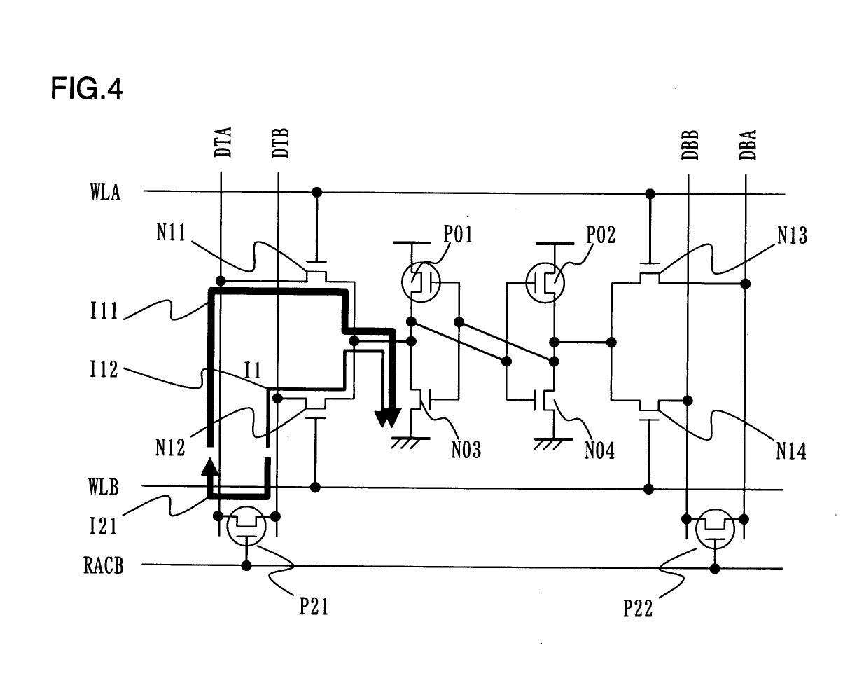

FIG. 4 illustrates the current paths in a case where the ON currents I11 and I12 of the access transistors N11 and N12 in FIG. 2 satisfy the relation I11>I12.

Owing to short-circuiting of the bit line DTA of the A port and the bit line DTB of the B port by the inter-port switch P21, the bit line DTB of the B port is discharged from the high level through the inter-port switch P21 via the path of the bit line DTA of the A port and access transistor N11 of the A port.

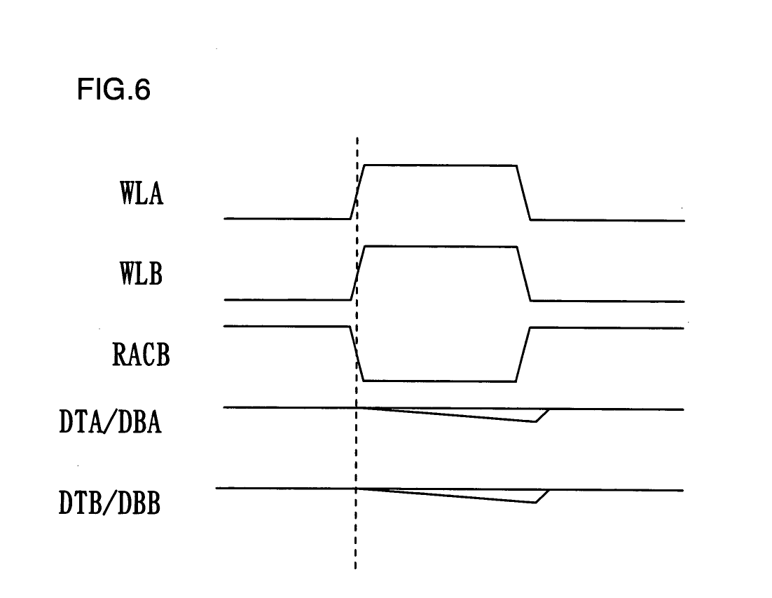

FIG. 6 is a diagram illustrating the waveforms of operation at this time. At the time of same-row-address access, the output RACB of the row-address comparator 103 is at the low level and the inter-port switches P21 and P22 both attain the ON state even though I11 [symbol] I12 holds. It will therefore be understood that the bit lines DTA and DTB are discharged uniformly through the inter-port switches P21 and P22 and that there is no influence from variations in the ON currents I11 and I12 of the access transistors N11 and N12 of the A and B ports.

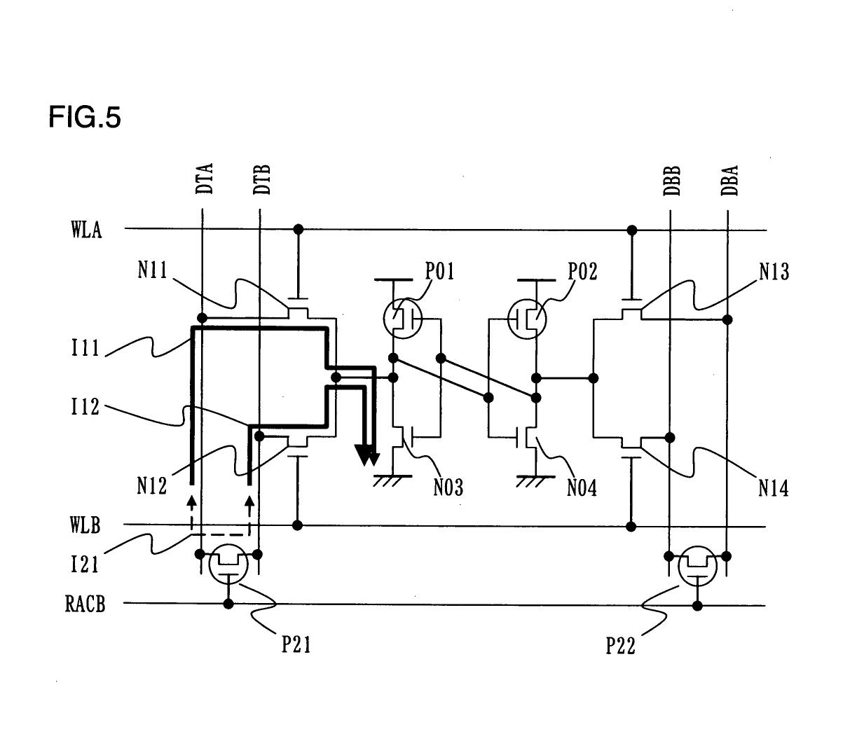

FIG. 5 illustrates the current paths in a case where the ON currents I11, I12 of the access transistors N11 and N12 in FIG. 2 satisfy the relation I11=I12.

Although the bit line DTA of the A port and the bit line DTB of the B port are short-circuited by the inter-port switch P21, the ON currents I11 and I12 of the access transistors N11 and N12 are the same. Therefore, the bit line DTA of the A port is discharged from the access transistor N11 of the A port and the bit line DTB of the B port is discharged from the access transistor N12 of the B port.

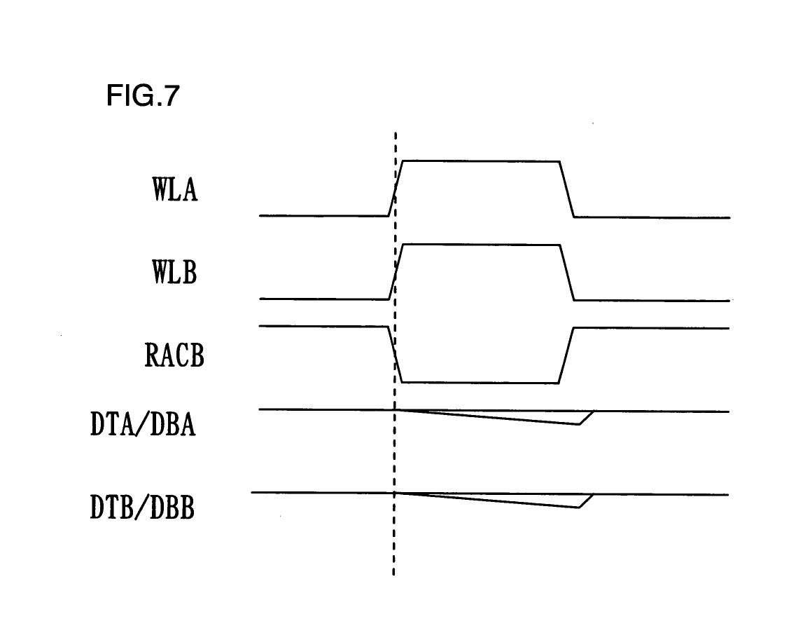

FIG. 7 is a diagram illustrating the waveforms of operation at this time. At the time of same-row-address access, the output RACB of the row-address comparator 103 is at the low level and the inter-port switches P21 and P22 both attain the ON state. Since the ON currents of the access transistors N11 and N12 at this time are related by I21=I22, migration of electric charge does not occur through the inter-port switches P21 and P22. However, since the ON currents of the access transistors of the A and B ports are equal, the bit lines DTA and DTB are discharged uniformly, as will be understood from FIG. 7.

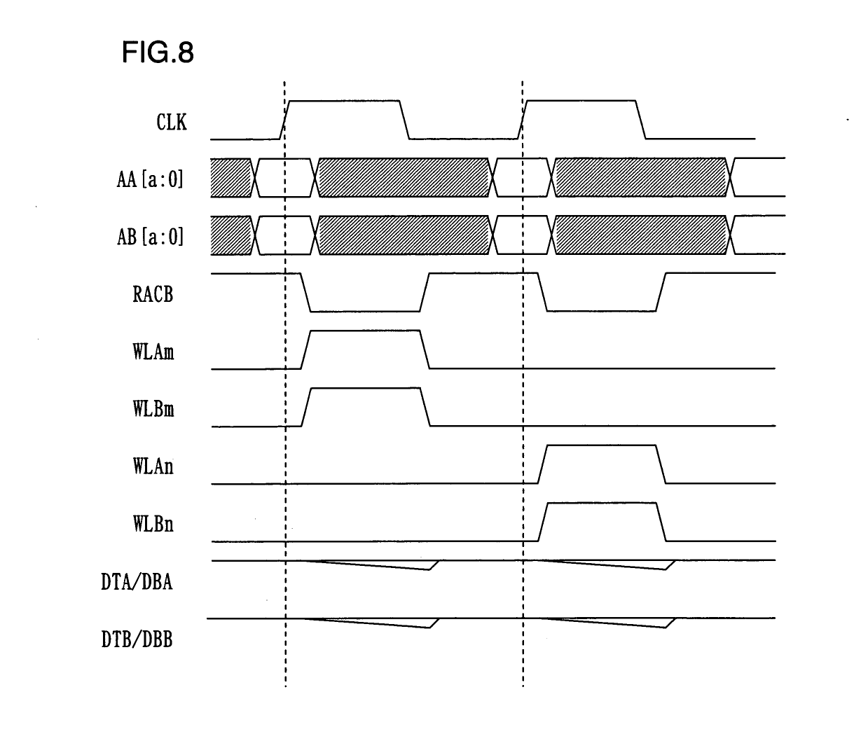

FIG. 8 illustrates, in the form of a timing chart, operation at the time of same-row-address access (RACB falls to the low level in the access cycle). This diagram indicates that even if it is assumed that either of the ON currents I11 and I12 of the access transistors N11 and N12 of the A and B ports has taken on a large value, there are no effects of port-to-port variation at all and the amounts of discharge of the bit line DTA of the A port and the bit line DTB of the B port from the high level are the same.

This exemplary embodiment is such that in a case where row addresses accessed at the A and B ports do not match each other, the row-address comparator 103 output the high level, the inter-port switches P21 and P22 turn off and the bit lines of the A and B ports are not shorted.

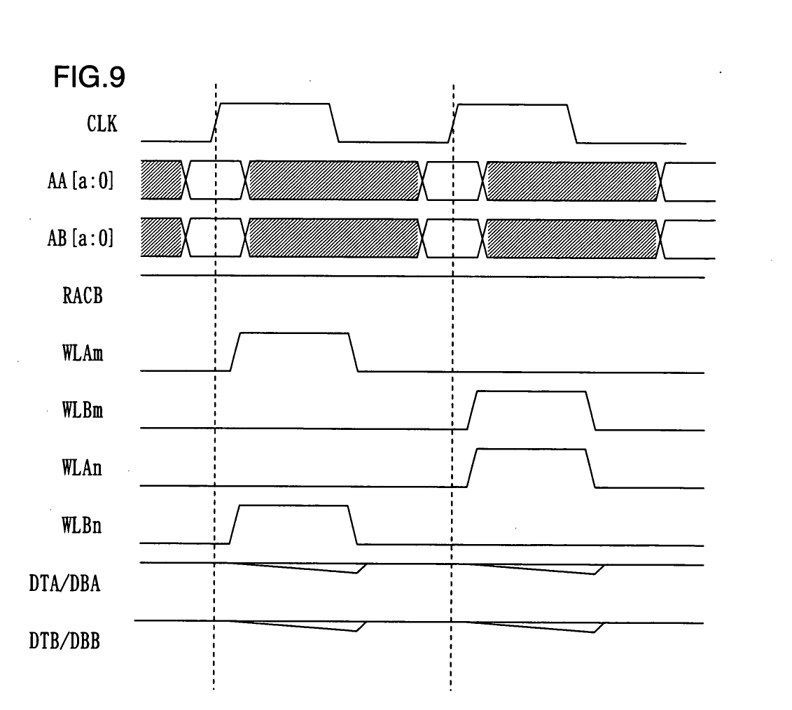

FIG. 9 illustrates, in the form of a timing chart, operation at the time of different-row-address access (RACB is held at the high level) at the A and B ports. In this case, each port operates as usual and the ports do not access the same cell. Hence there is no influence from port-to-port variation.

At the time of same-row-address access, the output RACB of the row-address comparator 103 falls to the low level, the inter-port switches P21 and P22 are turned on and the bit lines of the A and B ports are short-circuited by the inter-port switches P21 and P22, whereby the currents of the A and B ports are equalized in all of the bit lines.

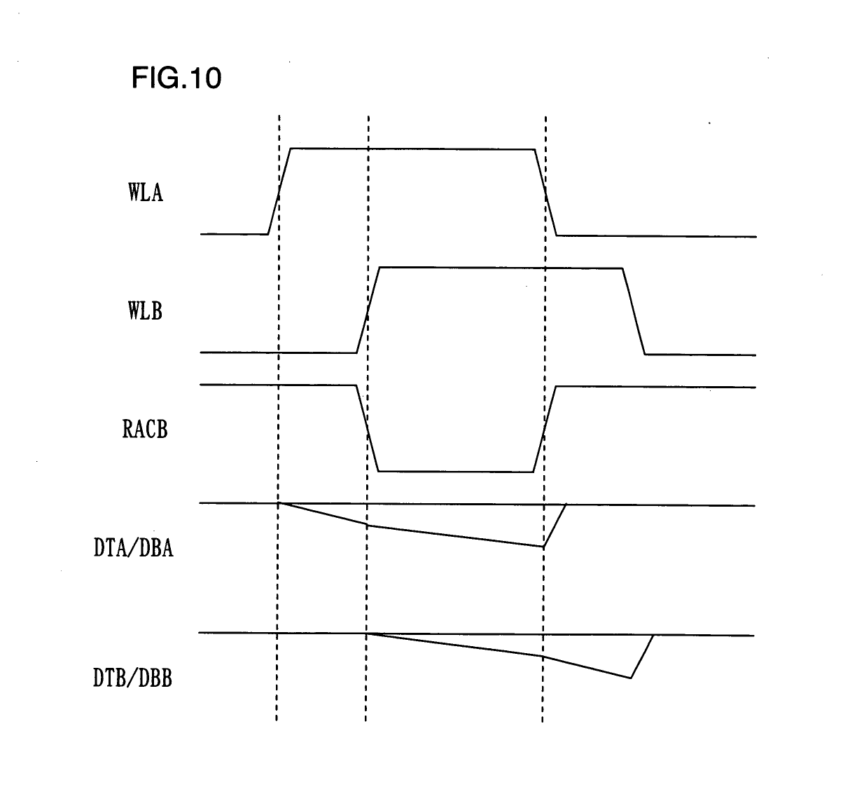

FIG. 10 is a diagram illustrating operation waveforms in a case where operation of the A port occurs first asynchronously (i.e., rise timing of word line WLA of the A port is earlier than rise timing of the word line WLB of the B port) in this exemplary embodiment.

While word line WLA of the A port and word line WLB of the B port are on at the same time, the output RACB of the row-address comparator 103 is at the low level and the inter-port switches P21 and P22 are on. In this period of time, therefore, there is no influence from port-to-port variation and discharge of the bit lines is performed at the same slope. If the earlier occurring access of the A port has ended, the word line WLA of the A port falls to the low level, the output RACB of the row-address comparator 103 attains the high level, the inter-port switches P21 and P22 are turned off and, from this time point onward, operation becomes single-port operation. During single-port access, concentration of current on one side does not occur, just as at the time of same-row-address access, and therefore there is little likelihood of inadequate discharge even in the case of an access transistor with a low capability for driving current.

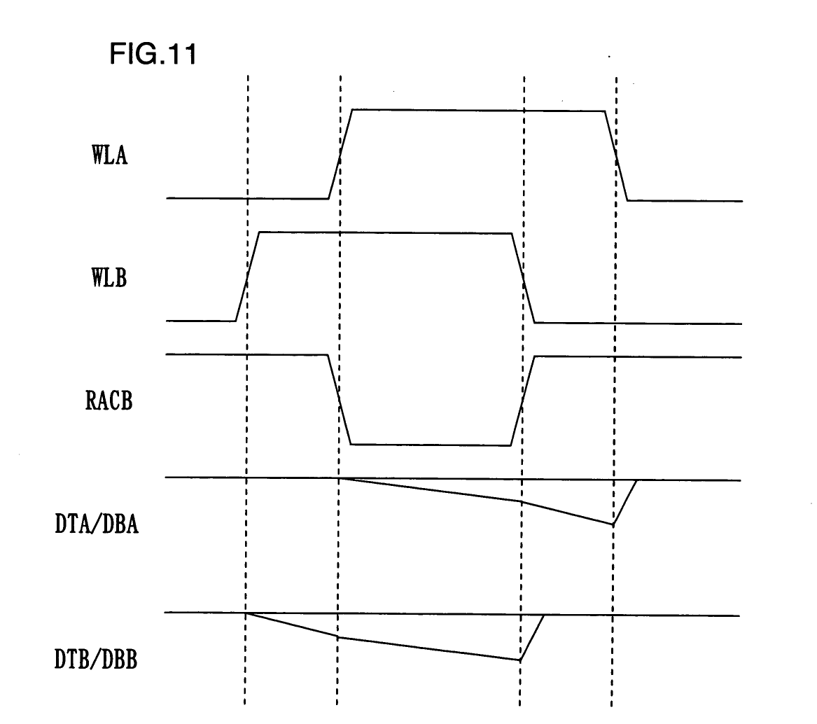

FIG. 11 is a diagram illustrating operation waveforms in a case where operation of the B port occurs first asynchronously (i.e., rise timing of word line WLB of the B port is earlier than rise timing of the word line WLA of the A port) in this exemplary embodiment. Operation in this case is similar to that of the case shown in FIG. 10.

Thus, even in a case where the A and B ports operates asynchronously, the inter-port switches P21 and P22 are turned on and the bit lines of the A and B ports are short-circuited only during the period of time in which the word lines WLA and WLB of the A and B ports are at the high level simultaneously. As a result, the same results are obtained.

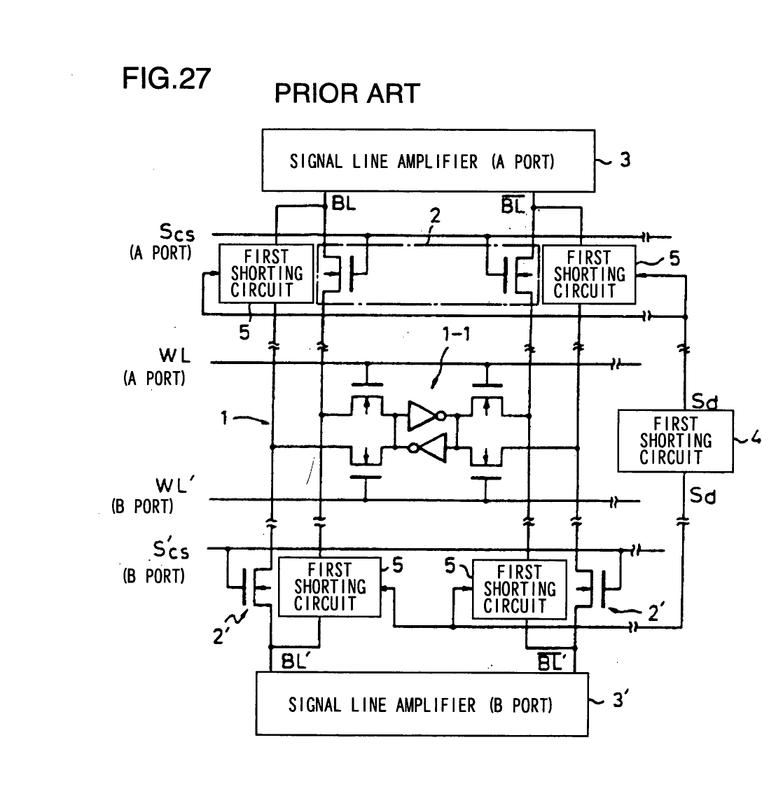

It should be noted that in the case of the arrangement of FIG. 27 in Patent Document 1, two switches are required on the side of the A port and two on the side of the B port.

In this exemplary embodiment, the inter-port switches P21 and P21 are for eliminating a current difference between the access transistors when the row addresses of the ports A and B are the same. Therefore, although switches are necessary between bit lines, two switches for every bit-line pair suffice. Owing to this difference in structure, the number of switches need only be half the number in the case of the arrangement of Patent Document 1. This results in a smaller increase in area.

In the first exemplary embodiment illustrated in FIG. 1, the inter-port switches P21 and P22 are drawn as being lumped at one location. However, it is possible for the inter-port switches disposed in distributed form.

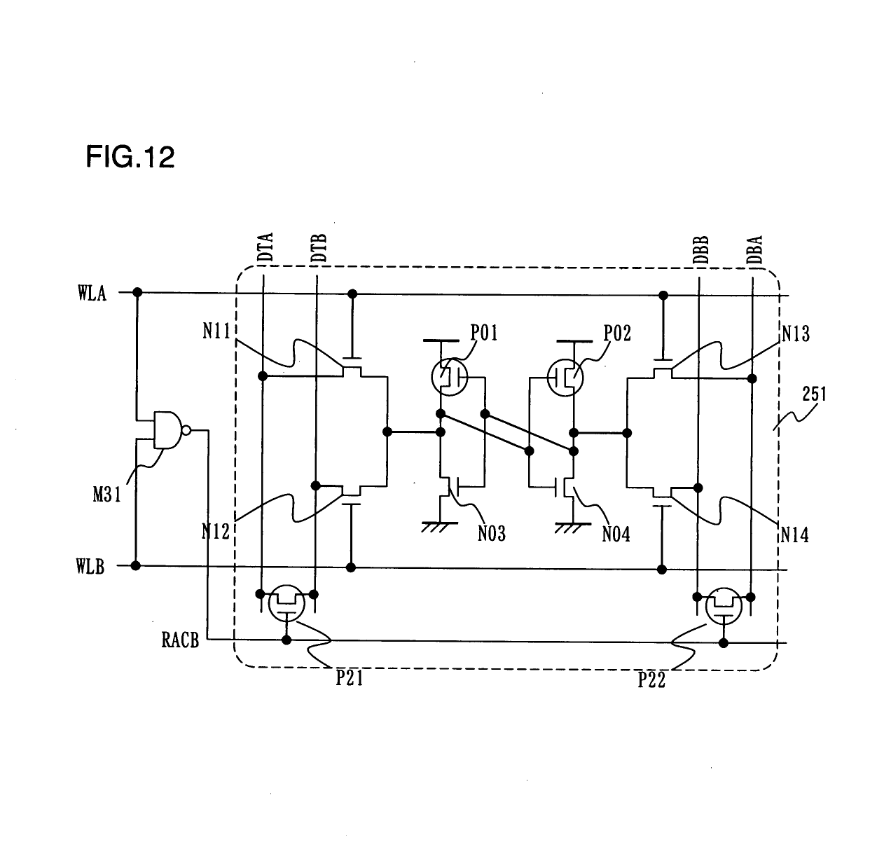

FIG. 12 is a diagram illustrating the configuration of a second exemplary embodiment of the present invention. FIG. 12 illustrates an example in which inter-port switches are provided for every memory cell. Comparison of row addresses is performed by a NAND date M31 (a row-address comparator). If the row addresses of the A and B ports match each other, the word lines WLA and WLB both are set to the high level, the output of the NAND date M31 goes to the low level and the inter-port switches P21 and P22 are turned on.

The NAND date M31 is inserted for every row, and the inter-port switches also are inserted in each memory cell. An area 251 in FIG. 12 corresponds to one memory cell. In the case of the circuit configuration of FIG. 12, the row-address comparator M31 is constituted by a two-input NAND gate, the inputs of which are connected to the word lines WLA and WLB. This simplifies the circuit configuration of the row-address comparator.

Furthermore, bit lines are short-circuited very near the access transistors that exhibit variation. Even if there is port-to-port variation, therefore, there is no influence from resistance of the bit lines and the currents of the A and B ports can be equalized effectively.

In comparison with the first exemplary embodiment shown in FIG. 1, the number of transistors increases by two in each memory cell and therefore a memory cell is composed of ten transistors. Accordingly, this is accompanied by an increase in area of at least 10/8=1.25 times.

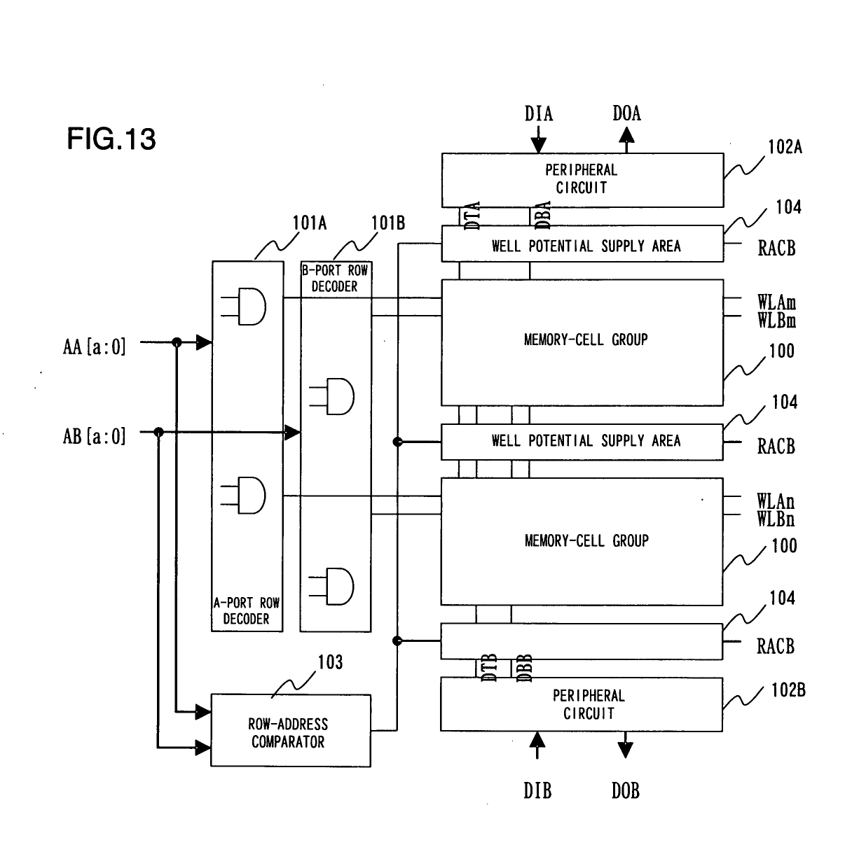

FIG. 13 is a diagram illustrating the configuration of a third exemplary embodiment of the present invention. This illustrates an example in which inter-port switches are dispersed in yet a different way. Here a case will be described in which the memory cells repeat in rows of 32, by way of example. The number of rows is not limited to 32 and may be 16 or 64 or even a number other than a power of 2. An area for supplying the potentials of N and P wells is provided between a 32-row memory-cell group 100 and the next 32-row memory-cell group 100.

In this exemplary embodiment, inter-port switches (not shown) for connecting the bit lines DTA and DTB/DBA and DBB of the A and B ports are disposed in a well potential supply area 104 and the output RACB of the row-address comparator 103 is wired to this well potential supply area 104.

In the case of the configuration shown FIG. 13, the arrangement is not one in which inter-port switches are provided in each memory cell in the manner of the second exemplary embodiment. Accordingly, this exemplary embodiment is not accompanied by the increase in area that occurs in the second exemplary embodiment.

In the first exemplary embodiment, the inter-port switches P21 and P22 are disposed in common with respect to all memory cells on the bit lines. This means that there is the possibility that the influence of the resistance of the bit lines can no longer be ignored. In the third exemplary embodiment, the inter-port switches are disposed every 32 rows, by way of example. As a result, there tends to be little influence from the resistance of the bit lines and the currents of the A and B ports can be equalized effectively.

Although the present invention has been described taking a dual-port RAM as an example in the foregoing exemplary embodiments, it is possible for the circuit configuration to be implemented by a multiport RAM (i.e., a RAM having three ports or more).

For example, there are a variety of dual-port RAMs that can be implemented. That is, examples of access regarding A and B ports are not only (Read/Write, Read/Write) (in which both the A and B ports perform both read and write) but also (Read, Read/Write) (in which the A ports performs read only and the B port performs both read and write), and (Read, Write) (in which the A port performs only read and the B port performs only write).

Further, there are a variety of three-port RAMs as well, such as (Read, Read, Write), (Read, Read, Read/Write). With regard to the row-address comparator and inter-port switches, in the case of a three-port RAM and, by way of example, a case where malfunction at the time of simultaneous read when same-address access is performed is to be prevented, if the (A port, B port, C port) configuration is (Read, Read, Write), then the inter-port switches are inserted only between the bit lines of the A and B ports and the row-address comparator detects coincidence between the row addresses of the A and B ports. Thus, implementation can be performed selectively.

Furthermore, it is possible for the present to be implemented not only with regard to an SRAM but also with regard to other RAMs having multiple ports.

The effects of the present invention will now be described.

In this exemplary embodiment, in FIG. 1, for example, memory-cell current is distributed evenly, without imbalance, between the bit lines DTA and bit lines DTB at the time of same-address access for the A and B ports, owing to the inter-port switches P21 and P22 provided between the bit lines of different ports. As a result, even if variations develop in the ON currents of the access transistors N11 and N12, equal currents flow into the bit lines of the A and B ports and it is possible to prevent a malfunction such as failure to achieve read-out. In FIG. 3, in a case where variations develop in the ON currents I11 and I12 of the access transistors N11 and N12 at the time of same-row-address access and the amounts of discharge regarding the bit lines DTA and DTB are, e.g., 0.1:10 in terms of ratio, which is tenfold difference, the inter-port switches are turned on in accordance with the present invention, thereby making the amounts of discharge of the bit lines DTA and DTB the same.

In Patent Document 1, etc., variations in access transistors are not taken into account and therefore the literature is devoid of the concept of providing the switches P21 and P22 between the bit lines of different ports.

From the standpoint of DFM (Design for Manufacturing), the present invention suppresses, by circuit means, variations that cannot be suppressed through fabrication process.

Furthermore, in the foregoing exemplary embodiments, the inter-port switches P21 and P22 differ from balancers or precharging means. Balancers and precharging means are circuits for performing presetting. The inter-port switches of the exemplary embodiments differ from presetting means.

Though the present invention has been described in accordance with the foregoing exemplary embodiments, the invention is not limited to these exemplary embodiments and it goes without saying that the invention covers various modifications and changes that would be obvious to those skilled in the art within the scope of the claims.

What is claimed is:

1. A semiconductor memory device comprising:
a memory cell connected to respective word lines of a plurality of ports and to respective bit lines of the plurality of ports; and
an inter-port switch for electrically coupling bit lines of different ports corresponding to the word lines of different ports, which are selected and driven simultaneously, from among the word lines of the plurality of ports connected to the memory cell.

2. The semiconductor memory device according to claim 1, wherein at least one said inter-port switch is disposed in the direction of an extension of the bit lines.

3. The semiconductor memory device according to claim 1, wherein a plurality of said inter-port switches are disposed in a prescribed spaced-apart relationship with each other in the direction of an extension of the bit lines.

4. The semiconductor memory device according to claim 1, wherein said inter-port switch is disposed in correspondence with each memory cell.

5. The semiconductor memory device according to claim 1, wherein the bit lines of the different ports which are electrically coupled via said inter-port switch, are driven by a drive transistor in the memory cell via respective access transistors of the different ports in the memory cell.

6. A semiconductor memory device comprising:
a memory cell connected to respective word lines of at least first and second ports and to respective bit-line pairs of at least first and second ports;
a first inter-port switch inserted between a positive-logic bit line of the bit-line pair of the first port and a positive-logic bit line of the bit-line pair of the second port;
a second inter-port switch inserted between a negative-logic bit line of the bit-line pair of the first port and a negative-logic bit line of the bit-line pair of the second port; and
a row-address comparator circuit for comparing row addresses of the first and second ports and outputting a signal, which turns on said first and second inter-port switches, when the two compared row addresses match each other.

7. The semiconductor memory device according to claim 6, wherein said row-address comparator circuit turns on said first and second inter-port switches when a word line of the first port and a word line of the second port become active simultaneously and turns off said first and second inter-port switches when one or both of the word line of the first port and word line of the second port is/are inactive.

8. The semiconductor memory device according to claim 6, wherein one set of said first and second inter-port switches is disposed with respect to a plurality of memory cells connected to the bit-line pairs of the first and second ports.

9. The semiconductor memory device according to claim 6, wherein one set each of said first and second inter-port switches is disposed in correspondence with each memory cell.

10. The semiconductor memory device according to claim 9, wherein said row-address comparator circuit includes a logic circuit for receiving word lines of the first and second ports as respective inputs instead of the row addresses of the first and second ports, and outputting a signal, which turns on said first and second inter-port switches, when the word lines of the first and second ports are both in the active state.

11. The semiconductor memory device according to claim 6, wherein a plurality of sets of said first and second inter-port switches are disposed in a dispersed manner in areas, each of which supplies a group of memory cells with well potential.

12. A semiconductor device including the semiconductor memory device set forth in claim 1.
